(19) United States
(12) Patent Application Publication
(10) Pub. No.: US 2004/0018749 A1
(43) Pub. Date: Jan. 29, 2004

(54) Method of decreasing brittleness of single crystals, semiconductor wafers, and solid-state devices

(76) Inventor: Benjamin F. Dorfman, San Francisco, CA (US)

Correspondence Address: Benjamin F. Dorfman, 438, 41st Avenue, San Francisco, CA, 94121, US

(21) Appl. No.: 10/190,133

(22) Filed: Jul. 8, 2002

(51) Int. Cl. H01L 21/469; H01L 21/31

(52) U.S. Cl. 438/783

(57) ABSTRACT

A method for decreasing brittleness of single crystals, semiconductor wafers and fragile elements of structures and devices is invented. The method is based on applying to the crystal surface a hard amorphous stabilized carbon low-stress coating possessing adhesion to the substrate that is equal to or exceeding the tensile strength of the protected crystalline material. The carbon coating is stabilized with at least two alloying elements: the first alloying element is selected from the group consisting of O, H, N, or their combinations; the second alloying element is selected from the group consisting of Si, B, transition metals, or their combinations. According to the invented method, the most effective structure of Si—O-stabilized hard amorphous carbon is graphite-like—diamond-like composite of atomic scale named QUASAM. Also according to the present invention, the diamond-like—quartz-like composite of atomic scale named DLN (American trade mark is DYLYN) may be applied to the crystalline structures, while the QUASAM coatings are still the most preferable ones. In accordance with the present invention, the thickness of coatings increasing the flexibility of single crystal structures are typically in the thickness range of 0.1 micrometers to 10 micrometers, while the thickness range of 0.20 to 2.5 micrometers is more preferable one in many cases, and the thickness range of 0.30 to 1.5 micrometers is still more preferable for silicon wafers, while the range of 0.35 to 1.0 micrometers is the most preferable one.

Also in accordance with the present invention, the multi-layer coatings and/or functionally graded coatings may be applied to increase the fracture toughness of crystalline materials or functional structures, while the first protective layer possesses the above indicated adhesion, mechanical properties and thickness. The results of extensive tests over 200 samples of protected silicon wafers are provided. Application of 0.35 to 1 micrometers thick coatings resulted with the 2 to 3-fold increase of critical angle of bending, while no one of the coated samples had been fractured at the bending angle lesser than the average value of uncoated wafers.

### FIELD OF THE INVENTION

The invention relates to single crystals, single crystal wafers of silicon and other electronic and photonic materials, and crystalline devices including computer chips, MEMS, solid-state lasers and other solid-state devices. More specifically, the invention relates to the technology decreasing brittleness of single crystals and wafers and fragility of single crystal devices.

### BACKGROUND INFORMATION

The contemporary electronics, photonics, sensor techniques are based on single crystalline materials, and the brittleness of those materials and fragility of the devices present increasingly serious problems for the technology. This problem becomes especially important for the 300-mm diameter silicon wafers. At this stage of the microelectronics and the entire semiconductor technology development, multiple problems occur at the final steps of wafer production, wafer packaging, and chip fabrication. One of alternative for the technology represents a double or even more than double increase of the wafer thickness which means a proportional increase in their cost. An economically sound approach allowing an essential increase in the wafer flexibility, while being technically feasible and compatible with the semiconductor technology, would be another and most desirable alternative.

Currently, the 300-mm diameter silicon wafers market is at its starting point, however, the demand for 300-mm wafers is growing extremely fast. It is expected that such a demand should be approaching 1500 million square inch equivalent (MSIE), e.g. 30% of the total worldwide silicon market in the year 2006. While the total wafer production is growing slowly or oscillates worldwide, the 300-mm wafer production will nearly double yearly and it is expected to become a dominant sector in the silicon wafer market in about 2010.

The wafer brittleness complicates all steps of all branches of solid-state technology, including computer, telecommunication, and sensor electronics and optics.

Modern semiconductor manufacturing equipment use automated wafer transport systems in order to reduce human handling of wafers. Due to the high sensibility and fragility of the wafers, the robot arms must be extremely accurate in loading and unloading wafers from a cassette, so as to avoid any rubbing or shock that could damage the wafers.

The problem of material brittleness and fragility of devices is particularly crucial during the manufacturing of Micro-Electro-Mechanical Systems (MEMS). Many processing steps are used, which can expose the fragile MEMS structures to mechanical damage during final steps of production and packaging.

It has been observed that a steady increase of the proportion of the fragile elements of electronic devices, such as flash memory chips, and especially MEMS, leads to a remarkable increase in brittleness of the entire structures of those devices, since the pronounced brittleness of the most fragile elements tends to dominate the mechanical properties of the integrated devices. Often, this results in an intolerable decrease in the device strength and reliability.

Thus, an inexpensive technology allowing an essential decrease in material brittleness and device structure fragility is in great demand.

Recently, a new family of stabilized diamond-like carbon materials QUASAM (U.S. Pat. No. 6,080,470, Dorfman), and DLN, also known under American trademark as Dylyn, (U.S. Pat. No. 5,352,493, Dorfman et al.; U.S. Pat. No. 5,466,431 Dorfman et al.), have been developed. Both QUASAM and DLN are of a similar chemical composition Cₙ[Si₁₋ₘ Oₘ], where typically n=3, ma≈0.45, and sp²:sp³ is in the range of 2:3 to 1:4 depending on growth conditions. While conventional DLC is an sp³:sp² carbon stabilized by internal stress instead of external pressure, the fine chemical stabilization in QUASAM and DLN shifts the carbon-diamond equilibrium, [see Dorfman, in Surfaces and Interfaces of Materials, Academic Press, 2001, Ed. by Dr. Nalwa, v.1]. Consequently, QUASAM and DLN are silica-stabilized virtually stress-independent carbon phases. DLN/Dylyn and QUASAM possess low stress, typically DLN possess stress ≦0.15 GPa, and QUASAM ≦0.05 GPa, i.e. within the limits of characterization errors in many samples, long-term thermal stability up to the temperature range 430 and 650° C. correspondingly, and short-term thermal stability up to 500° C. and −850° C. correspondingly. Both materials are atomically smooth, pore-free and uniform starting from the first atomic layers. Due to their chemical composition comprising of chemically complimentary elements O, C, and Si, both QUASAM and DLN possess nearly universal adhesion to any substrate. Most importantly, the QUASAM coatings demonstrate adhesion to many substrates including silicon that exceeds the innate strength of the corresponding substrates. The sp³/sp² ratio in QUASAM and DLN may be varied during the deposition process thus providing coatings with required functional profile of mechanical properties, while preserving the coating integrity and preventing buildup of stress.

Apart from these common features, DLN is a composite structure formed by mutually penetrating diamond-like and quartz-like network, while in QUASAM carbon and silica form a strongly bonded structure. The specific gravity of these carbon phases is also different: 1.8 to 2.25 g/cm3 (2.2-typical value) in DLN, and 1.3 to 1.75 g/cm3 (1.5-1.6 typical values) in QUASAM. Most importantly, DLN has a pure amorphous atomic arrangement, while the QUASAM material possesses a hierarchical structure with slight one-axis anisotropy. Such a structure combining diamond-like features with the best features of graphite makes QUASAM film a unique coating for material enforcement.

Theoretically, graphite in plane is harder and stronger than diamond; however, weak inter-plane bonds make graphite a soft, low-modulus material. Over the second half of past century, many efforts have been devoted for creating a graphite-based material realizing a theoretical strength of graphite planes in a bulk three-dimensional structure. In part, those efforts resulted successfully with creating super-strong carbon fibers and carbon-composites. Still, those materials are soft, and graphite fibers possess one-dimensional strength only. The QUASAM material combines both major carbon forms—graphite and diamond—an atomic-scale hierarchical carbon-carbon composite structure, wherein graphite bonded with a diamond framework demonstrates the nearly theoretical limit of its mechanical strength in plane.

QUASAM is the first carbon-carbon composite on atomic scale, the first composite comprising the major carbon forms, diamond and graphite, as well as the first hard hierarchical composite. It is particularly important that such a hierarchical composite structure is formed by a self-regulated process; this provides the QUASAM technology with high performance and makes it economically sound. As a result, QUASAM is already holding many records: it is the hardest of all materials possessing density below 2.0; the lightest of all hard materials possessing hardness above 2O GPA; the only material of all known solids preserving virtually constant mechanical and thermal properties in the temperature range from low temperatures to about 600 C.; the only known diamond-like matter that is virtually free from stress; the only known diamond-like matter produced as a freestanding stable matter. It is especially important for the present invention, that QUASAM represents the only known hard material (not excluding diamond) possessing fracture toughness above 4; indeed, the best QUASAM samples reaches 40, approaching steel.

We have conducted extensive research of stabilized hard amorphous carbon coatings upon various singe crystal substrates, including semiconductors silicon, germanium, A(supIII), B(supV), A(supII), B(supVI), mountain crystal, topaz, and other crystals in a broad range of the coating thickness, growth deposition and structure, and found there exists a relatively narrow range of the coating characteristics, wherein a strong increase of the crystal fracture toughness is observed, and the coated single crystal plates, such as silicon wafers used in the electronic and semi-conductor industries, display an essential increase of their flexibility. Next, a systematic examination of silicon wafers coated with stabilized hard amorphous carbon of major families QUASAM and DLN/Dylyn had been conducted, and the above named range of the coating characteristics have been precisely specified and statistically reliably proven.

QUASAM may be deposited upon semiconductors, metals, or ceramics and produced as freestanding material. The strength of Si-QUASAM interface bonding exceeds the intrinsic silicon strength. It was shown [see Dorfman, in Surfaces and Interfaces of Materials, Academic Press, 2001, Ed. by Dr. Nalwa, v.1] that QUASAM layer with thickness of about 200 to 300 micrometers dramatically increases the fracture toughness and thermal shock resistance of silicon wafers. Although these results are of great importance for MEMS and various structures and devices wherein QUASAM would be applied as a construction material, such thick layers of hard carbon matter may not be implemented into silicon chips technology or other existing technologies.

This invention adresses the problem of crystals and crystalline wafer brittleness and solid-state device fragility in existing technologies of solid-state electronics and other devices and structures, and it suggests a relatively simple, economically sound, and industrially feasible solution of the problem.

### BRIEF DESCRIPTION OF THE DRAWINGS

The accompanying drawings illustrate a high-precision bending machine applied for examination of the critical angle of bending of silicon wafers and the distribution functions of critical deformation found for uncoated silicon wafers and wafers coated with stabilized hard amorphous carbon coatings of various thicknesses and structure according to the present invention and, together with the description, serve to explain the principles of the invention.

FIG. 1 shows a schematic view of the high-precision bending machine. 1—steel base, 2—wafer, 3—steel rod, 4—hard steel pyramid, 5—direction of the load. L—length of cantilever, Δ-deformation.

FIG. 2 shows distribution functions, e.g. dependence of relative probability of fracture on a relative deformation for uncoated silicon samples and samples coated with stabilized hard amorphous carbon coatings according to the present invention. FIG. 2.

### DESCRIPTION OF THE PREFERRED EMBODIMENTS

The present invention addresses the problem of improving the resistance of crystals, wafers and solid-state devices and structures to mechanical deformation and increasing flexibility of said devices and structures and mechanical strength of the devices and structures with a support of hard amorphous stabilized carbon coatings possessing adhesion to the substrate that is equal to or exceeds the tensile strength of the protected crystalline material. Thus, the problem is solved, according to the invention, by reinforcing the surface of materials and devices with a coating that essentially increases the critical deformation producing initial cracks in a protected crystalline solid, and enhances its resistance to the crack propagation. Such a coating very well satisfies the need for increasing of flexibility and providing sufficient strength for crystals and crystalline devices, and it also increases their thermal shock resistance. The deposition technology of such coatings is relatively cheap, and completely compatible with existing microelectronic technology.

According to the present invention, there exists a relatively narrow thickness range of the hard amorphous stabilized carbon coatings upon a brittle substrate that provides such a substrate with a strong increase of its flexibility. This optimum thickness range depends on the nature of the substrate and the structure of the coatings, and on the whole comprises the coating thicknesses from about 0.1 micrometer to about 10 micrometers, while in the most typical cases the effective coating thickness range expands from ˜0.2 minimum to ˜3.0 micrometers maximum, while the optimum range is even more narrowed for every specific material. The most extensive examination was conducted for silicon wafers, and the detailed results are provided below.

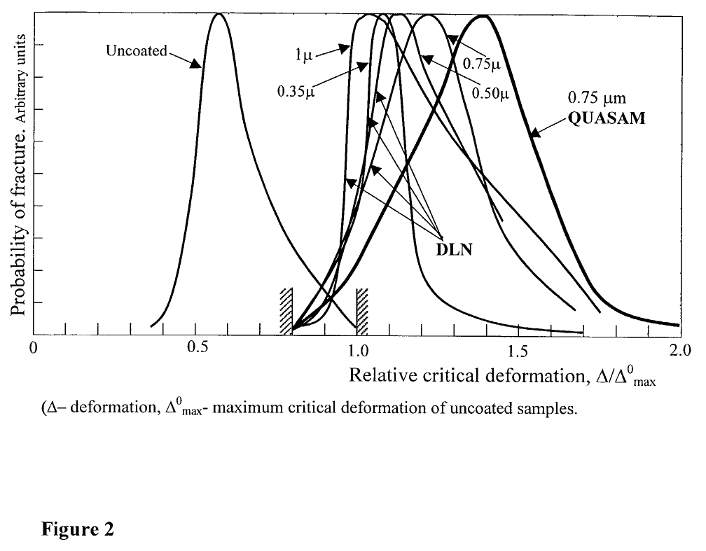

Referring to the drawings, in particular to the graphs 2-6, and especially graph 6 in FIG. 2, there is shown a strong increase of flexibility of silicon wafers protected with stabilized hard amorphous carbon coatings, especially with the QUASAM coatings. The distribution functions on the FIG. 2 are plotted based on an extensive examination of cantilevers having been cut from silicon wafers used by the electronics industry; all silicon wafers had thicknesses in the range of 400±10 micrometers, crystallographic orientation (100); 4″ diameter. The surface of the front sides of the wafers had been finished by diamond polishing with a chemical-mechanical final step of surface preparation according to the electronic industry standard. The back sides of all wafers were finished with diamond polishing and finally subjected to a chemical etching according to the contemporary technology standard. For comparison, some wafers weren't finished chemically from the back side, thus the hidden nano-cracks were left in the near-surface layer. It is not included in the summary data used for calculation of distribution functions shown on FIG. 2, but some example series are shown in the Table.

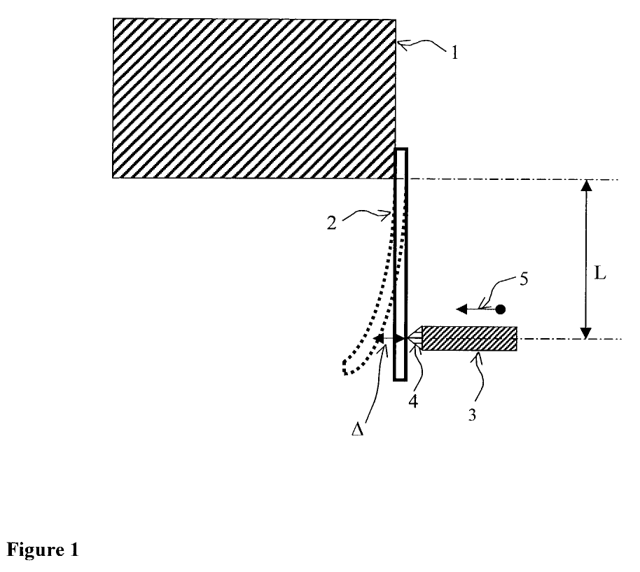

Two approaches for a cantilever cutting test were used in this examination: 1) the main series of samples had been sown with a diamond saw; 2) a few series of samples had been scribed and broken according to the old technology standard for comparison. Also for comparison, the cutting prior to the coatings deposition, and after deposition have been tested. Furthermore, four kinds of cantilever geometry had been applied: 5-mm wide with L=30-mm, where L is active arm of the bending, as designated in FIG. 1; 4-mm wide, L=30 mm; 5-mm wide, L=50 mm, and 4-mm wide, L=50 mm. The coatings had been applied to the back sides of the examined wafers. Deformation from both back sides and front sides was tested, and critical deformation Δcr had been defined for each tested samples, when said sample was fractured. The precision of Δcr measurements was 0.1 mm. Maximum deformation Δ in this testing machine is 19 mm. The results were found in a good agreement with a linear scaling regarding to average value of the Δcr/L ratio. The width of cantilever didn't essentially change the results.

The distribution functions in FIG. 2 are plotted based on all received results for the proper prepared samples. On this graph, the values of critical deformation, e.g. deformation when the examined samples were broken, are defined relatively to the average value of critical deformation found for uncoated samples of the identical geometry, while all the samples, coated and uncoated, were cut from similar wafers of electronic industry quality: 1—uncoated samples, 2-5—samples coated with DLN coatings correspondingly 0.35-μm, 0.50-μm, 0.75-μm, 1.0-μm thick; 6—samples coated with 0.75-μm thick QUASAM coatings, as indicated on the graphs 2-6.

The Table shows the exact results of the tests for L=50 mm cantilevers with DLN coatings, QUASAM coatings, and uncoated. The tested sample was considered as a satisfactory one if its critical deformation was equal or exceeded the average critical deformation of the uncoated samples. The opposite case was considered as a failure. As it shows in the Table, all tested series of appropriately coated samples displayed the 100% yield of good, while series of the uncoated samples never displayed a yield of good exceeding 50%, and in some series the yield was below 50%, or even 0% under the above defined requirements.

As it is shown in the Table, the 0.35-micrometers, 0.5-micrometers, 0.75-micrometers, and 1.0-micrometers thick coatings were most effective; in the Table they are highlighted with bold fonts. The 0.2-micrometers and 3.0-micrometers thick coatings, although they displayed some positive effect, were less effective. Thick coatings result with strong concentration of stress near the coating/silicon interfaces along the edges of structure, while the coatings in the range of thickness≦0.2 micrometers may not effectively stop the cracks propagation in silicon wafers.

The old cutting technology, based on the scribing and breaking operations, produces multiple micro-cracks along the chip edges, and this results in essentially lesser flexibility of the samples: the value of critical deformation when the uncoated samples were fractured, decreased by about 20% in the case of a proper chemical treatment of the wafer back side. In the case of only mechanical finishing of back side, the loss of flexibility was even more dramatic, and even with a lower requirements, e.g. taking into evaluation a low value of the minimum allowed critical deformation, the yield of “good product” under deformation from back side approaches “0”. Even in those conditions, the 1-micrometers thick coatings were found effective.

Under conditions of the proper preparation of the wafer back sides and samples cutting by the diamond saw, uncoated samples displayed yield of “good product” of 50% in the case of deformation from the wafer front sides, and 14% to 33% in the case of deformation from the wafer back sides.

TABLE 1
Summary results for QUASAM/Silicon and DLN/Silicon. Wafers (100).

| Film | Side of | | | | | | | | | |
|---|---|---|---|---|---|---|---|---|---|---|
| thickness | applied | The sample under in series | | | | | | Yield | | Samples description. |
| Coated side | force | 1 | 2 | 3 | 4 | 5 | 6 | Yield | Δₙₒᵣₘ | Notes |
| Uncoated | FS | 11.0 | 10.6 | 9.8 | 6.5 | 5.2 | 5.1 | 50% | 8 | Strip wide/Cantilever |
| | BS | 10.0 | 9.3 | 8.1 | 6.9 | 6.0 | 5.5 | 50% | mm | length. 4 mm/50 mm |
| | BS | 6.5 | 5 | 9 | 7 | 8 | 6 | 33% | | BS chemically |
| | BS | 6 | 5 | 5 | 7 | 6 | 6.5 | 14% | | finished, and “chips” |
| | | 8 | 5.5 | — | — | — | — | | | (strip samples) had |
| 0.35 μm/BS | BS | 15 | 8 | 9.5 | 8.5 | 12.5 | 10.5 | 100% | | been sawn up with |
| | | 11 | 8.5 | 9 | 10 | 12 | 9.5 | 100% | | diamond saw accord- |
| | | 11 | 9 | — | — | — | — | | | ing to the electronic |
| 0.5 μm/BS | BS | 12.5 | 12 | 11 | 11 | 11 | 10 | 100% | | industry standards |
| | | 8 | — | — | — | — | — | | | after film |
| | | 14 | 12.2 | 12 | 12 | 12 | 12 | 100% | | deposition. Samples |
| | | 11.5 | — | — | — | — | — | | | considered as a good |
| | | 13 | 14 | 13 | 10 | 9.5 | 14 | 100% | | one if Δ ± Δₙₒᵣₘ |
| | | 10 | 10 | | | | | | | FS - front side; BS - |
| | FS | 11 | 10.7 | 10.5 | 10 | 8 | — | 100% | | back side. The major |
| 0.75 μm/BS | BS | 11.5 | 10.5 | 16 | 8 | 10 | 13 | 100% | | series marked with |
| | | 12 | 8.5 | 12 | 12 | 15 | 10 | 100% | | bold fonts |
| 1 μm/BS | BS | 14 | 12 | 12 | 10 | 14 | 16 | 100% | | * 19 mm - limit of |
| | | 13 | 12 | 11 | 17 | — | — | | | testing machine. The |
| | | 11.6 | 10.5 | 14.0 | 14.1 | 12,0 | — | 100% | | sample was broken |
| | | 11.5 | 10.5 | 10 | 9.7 | 9.5 | 9.1 | 100% | | after multiple (4 |
| | | 9 | 8.6 | — | — | — | — | | | times) deformations |
| | FS | 9.5 | 9.1 | 9.0 | 9.0 | 8.9 | 8.6 | 100% | | up to the limit. ** |
| 0.75 μm/BS | BS | 17 | 13 | 10 | 13.5 | 15 | 15 | 100% | | Relatively poor |
| QUASAM | | 13.5 | 15.5 | 13 | 14 | 11 | 8 | 100% | | adhesion. |
| | | 9.5 | 11 | 14 | 13 | >19* | | 100% | | *** Wafers were cut |
| 0.2 μm/BS | BS | 9.5 | 9.5 | 8.5 | 8 | 8 | 7 | 72% | | prior to the fllm |
| *** | | — | — | — | — | — | 6.5 | | | deposition. |
| 3 μm/BS** | BS | 12.8 | 8.5 | 8 | 8 | 7 | 6.5 | 67% | | All coatings except |
| 3 μm/FS** | FS | 8.5 | 8.5 | 8 | 5.5 | — | — | 75% | | of marked |
| 3 μm/BS | BS | 13.5 | 10 | 10 | 9.5 | 9 | 8 | 100% | | QUASAM, are DLN. |
| 3 μm/FS | FS | 9 | 5.5 | 5 | 5 | — | — | 25% | | |
| Uncoated | FS | 8.1 | 7.7 | 5.1 | 3.5 | — | — | 50% | 6.5 | 380 μm/5 mm/5 cm |
| 1 μm/FS | | 8 | 8 | 7.3 | 7 | — | — | 100% | | BS mechanically |
| 1 μm/FS&BS | | 8 | 7 | 7 | 6.5 | — | — | 100% | | polished. |
| Uncoated | BS | 4.8 | 4 | 4 | 3.5 | — | — | 0% | 5 | Scratched and |
| 1 μm/FS | | 6.5 | 6 | 6 | 5 | — | — | 100% | | broken into strips |
| 1 μm/FS&BS | | 6 | 6 | 5 | 4 | — | — | 75% | | after film deposition. |

As it is shown in the Table, the 0.35-micrometers, 0.5-micrometers, 0.75-micrometers, and 1.0-micrometers thick coatings on the back sides of wafers secured a strong increase of the wafer flexibility and the 100% yield of “good product” in all tested series. It is important and remarkable that no one tested coated samples displayed was fractured at deformation below 0.8 of maximum critical deformation displayed by uncoated samples, while many uncoated samples were fractured at deformation of about 50% of said maximum value. Contrary, a statistically significant number of 26 tested coated samples displayed critical deformation exceeding on 30 to 70% of maximum value observed for uncoated wafers, and some samples were not fractured even under maximum deformation available on this testing machine.

It is also shown, that even 0.35-micrometer thick coatings produce reliable increase of the wafer flexibility, although the 0.75-micrometer thick coatings, especially the QUASAM coatings provide a giant, over 2-fold shift of the maximum of distribution function.

In general, application of 0.35 to 1-micrometer thick coatings resulted with the 2 to 3-fold increase of critical angle of bending, while no one of the coated samples had been fractured at the bending angle lesser than the average value of uncoated wafers.

It is also very important, that the critical deformation of the all tested uncoated samples never exceeded 10 mm from back side or 11 mm from front side, while many coated samples, especially with QUASAM coatings, displayed 20% to over 50% of these utmost maximum values of uncoated samples. Indeed, one of the coated samples wasn't fractured under maximum deformation allowed with testing machine, e.g. 19 mm. This sample sustained a triple bending up to Δ=19 mm having been still intact, thus demonstrating an exceptionally high flexibility and indicating still existing potential for the invented method perfection.

In the case of Cr-QUASAM atomic-scale composite 1.0-micrometer thick coatings with resistivity 2×10(sup-3) Om.cm. the results were similar to the above described, while the maximum value of critical deformation was 15 mm, that is 50% superior to the maximum critical deformation for uncoated wafer, while is inferior to the results obtained with the pure QUASAM coatings.

In summary of all conducted researches and according to the present invention, the entire range of thickness of the hard amorphous stabilized carbon coatings increasing flexibility of single crystals structures is typically in the range of 0.1 micrometers to 10 micrometers, while the thickness range of 0.30 to 2.5 micrometers is more preferable one in many cases, and the thickness range of 0.35 to 1.5 micrometers is the most preferable for silicon wafers.

Also in accordance with the present invention, the multi-layer coatings and/or functionally graded coatings may be applied to increase the fracture toughness of crystalline materials or functional structures, while the first protective layer possesses the above indicated adhesion, mechanical properties and thickness.

What is claimed is:

1. A method for decreasing brittleness of single crystals, semiconductor wafers and fragile elements of structures and devices comprising the step of applying to the crystal surface a hard amorphous carbon coating possessing adhesion to the substrate that is equal to or exceeds the tensile strength of protected crystalline material; said carbon coating is stabilized with at least two alloying elements: the first alloying element is selected from the group consisting of O, H, N, or their combinations; the second alloying element is selected from the group consisting of Si, B, transition metals, or their combinations, and optionally said carbon coating may comprise of hydrogen having a concentration no greater than 50 atomic % with respect to the total composition; said carbon coating possesses the as-grown stress below 1.0 GPa, more preferably below 0.2 GPa, still more preferably below 0.05 GPa.

2. A method for decreasing brittleness of single crystals, semiconductor wafers and fragile elements of structures and devices according to claim 1, wherein said stabilized hard amorphous carbon comprises an sp². bonded graphite-like layer structure and an sp³ bonded three-dimensional diamond-like framework, wherein said graphite-like layered structure is penetrated and bonded together by said diamond-like framework, the carbon content in said material comprises from about 40 to about 90 atomic % of the sum of carbon plus said first and said second alloying elements.

3. A method for decreasing brittleness of single crystals, semiconductor wafers and fragile elements of structures and devices according to claim 2, wherein the ratio between said graphite-like sp² bonds and said diamond-like sp³ bonds can be modulated in a nanometer and/or micrometer scale such that a hierarchical structured material is formed.

4. A method for decreasing brittleness of single crystals, semiconductor wafers and fragile elements of structures and devices according to claim 2, wherein the ratio between said graphite-like sp² bonds and said diamond-like sp³ bonds is functionally graded in a nanometer and/or micrometer scale.

5. A method for decreasing brittleness of single crystals, semiconductor wafers and fragile elements of structures and devices according to claim 1, wherein said stabilized hard amorphous carbon formed from interpenetrating networks of carbon, hydrogen and alloying elements, comprising a first network of predominantly sp³ bonded carbon in a diamond-like carbon network stabilized by hydrogen, and at least one network made from alloying elements, including a second silicon network stabilized by oxygen and, optionally, a third metal network of metal elements from groups 1-7b and 8b of the periodic table wherein the carbon content of the solid state material is at least 40 atomic % of the sum of carbon and the other alloying elements, the hydrogen content is up to about 40 atomic % of the carbon concentration, and the sum of concentration of alloying elements is greater than about 2 atomic % of the sum of carbon, hydrogen, and the alloying elements.

6. A method for decreasing brittleness of single crystals, semiconductor wafers and fragile elements of structures and devices according to claim 1, wherein the alloying elements comprise alone or in combination B, Li, Na, Si, Ge, Te, O, Mo, W, Ta, Nb, Pd, It, Pt, V, Fe, Co, Mg, Mn, Ni, Ti, Zr, Cr, Re, Hf, Cu, Ag, and Au.

7. A method for decreasing brittleness of single crystals, semiconductor wafers and fragile elements of structures and devices according to claim 6, wherein the metal content is in the rage of 10 to 50 atomic %, but most preferable it is in the range of 15 to 40 atomic %.

8. A method for decreasing brittleness of single crystals, semiconductor wafers and fragile elements of constructions and devices according to claim 1, wherein said stabilized hard amorphous carbon coatings possess a thickness in the range of 0.1 micrometers to 10 micrometers, while the thickness range of 0.30 to 2.5 micrometers is the more preferable one.

9. A method for decreasing brittleness of semiconductor wafers according to claim 1, wherein said stabilized hard amorphous carbon coatings are applied to the back side of the silicon wafers, the thickness of said coatings is in the range of 0.20 to 2.5 micrometers, while the range of 0.3 to 1.5 micrometers is more preferable, and the range of 0.35 to 1.0 micrometer is the most preferable.

10. A method for decreasing brittleness of single crystals, semiconductor wafers and fragile elements of structures and devices according to claim 1, wherein said stabilized hard amorphous carbon coatings are applied to the front side of electronic, optical, or micro-electro-mechanical systems (MEMS) devices.

11. A method for decreasing brittleness of single crystals, semiconductor wafers and fragile elements of the structures and devices according to claim 10, wherein said stabilized hard amorphous carbon coatings are applied to the selected elements of front side of the electronic, optical, or micro-electro-mechanical systems (MEMS) devices.
